(19) United States
(12) Patent Application Publication
(10) Pub. No.: US 2025/0379457 A1
(43) Pub. Date: Dec. 11, 2025

(54) A Battery Energy Storage System

(71) Applicant: SUNVERTEC PTY LTD, Wangara (AU)

(72) Inventors: Kevin DAVIES, Wangara (AU); Alexander DAVIES, Perth (AU)

(21) Appl. No.: 18/878,341

(22) PCT Filed: Jun. 22, 2023
(86) PCT No.: PCT/IB2023/056471

§ 371 Date: Dec. 23, 2024

(30) Foreign Application Priority Data
Jun. 22, 2022 (AU) 2022901722

(51) Int. Cl. H02J 7/00; H01M 50/244; H01M 50/264; H01M 50/291; H01M 50/293; H01M 50/516; H01M 50/519; H01M 50/569; H01M 50/588

(52) U.S. Cl. CPC H02J 7/0019; H01M 50/244; H01M 50/264; H01M 50/291; H01M 50/293; H01M 50/516; H01M 50/519; H01M 50/569; H01M 50/588; H02J 7/007182

(57) ABSTRACT

The invention is an energy storage system, comprising: a plurality of elongated compartments, each designed to house a string of energy storage cells; each compartment is equipped with accessible openings, engineered to facilitate the easy installation and removal of the storage cells; the compartments being architected to host two or more storage cells, positioned adjacently within its extremities; a retaining mechanism is also incorporated, which serves to hold the string of cells firmly pressed together, thereby forming a reliable current path; the system incorporates a balancing mechanism; this mechanism includes a balancing system that comprises electrical tabs connecting the junctions of adjacent cells and a mechanism capable of moving charge into and out of these tabs. This movement of charge facilitates charging or discharging of the cells, thereby maintaining balanced voltages across the system.

### FIELD OF THE INVENTION

The present invention pertains to the field of energy storage systems, specifically focusing on developing an efficient, economical, and serviceable solution that can be adapted across a variety of applications, ranging from residential to grid-scale energy storage.

### BACKGROUND OF THE INVENTION

The increasing urgency to mitigate climate change has pushed for rapid advancements in renewable energy technologies. These technologies, such as solar and wind, offer a promising future with abundant, cost-effective energy that has minimal environmental impact. Despite this potential, renewable energy faces a significant limitation in its intermittency—these sources generate energy only when the sun shines or the wind blows, and not necessarily when energy is needed. To harness their full potential and transition from the fossil fuel-based energy system, efficient and economical energy storage solutions are needed.

Energy storage systems offer a means to match energy generation from renewable sources with demand. They store the surplus energy produced during periods of high generation and low demand, releasing it back to the grid when the demand exceeds the generation. Thus, they offer the possibility of fully exploiting renewable energy resources, helping to reduce dependence on fossil fuels, and significantly lowering greenhouse gas emissions.

Over the years, numerous energy storage systems have been developed, ranging from pumped-hydro storage to battery technologies such as lead-acid, lithium-ion, and newer technologies like solid-state batteries and flow batteries. However, these solutions often come with their own set of challenges. For instance, pumped-hydro storage, while effective, requires large spaces and specific geographical features, making it unsuitable for most applications. Battery technologies, on the other hand, can be costly, have varying degrees of energy density, and often require intricate Battery Management Systems (BMS) to ensure safe and efficient operation. The lifespan and maintenance of these systems also pose a considerable challenge, contributing to high capital costs and electronic waste.

In addition, the need for efficient energy storage is not limited to the grid-scale. Energy storage is also crucial at smaller scales, such as in residential, commercial, and industrial settings. These applications present their own unique challenges, such as spatial constraints, unique energy requirements, and a higher need for safety and reliability.

Current solutions often require unique product designs for each application area, making them expensive and difficult to service. For instance, residential solar/battery systems often require hybrid inverters that combine functions of both solar inverters and battery inverters. Moreover, every grid-scale application demands a bespoke design due to its specific energy requirements and installation environments. These challenges compound the difficulty in creating affordable and efficient energy storage solutions that can be readily deployed and serviced.

Despite the progress in this field, the existing technologies and solutions do not adequately address these challenges, posing a significant obstacle to the widespread adoption of renewable energy. There is thus an urgent need for an energy storage solution that is economical, efficient, long-lasting, easy to service, and adaptable across various application areas. The present invention aims to address these shortcomings and provide such a solution.

### DESCRIPTION OF THE DRAWINGS

FIG. 1 is a Top View of Extruded Aluminium Tube for Battery Storage and presents an overhead view of an extruded aluminium tube designed for battery storage. This view reveals the efficient organization and safety measures taken into consideration for this battery system. Key components include battery cells and a PCB, extruded screw holes, double insulation, PCB clamps, and overlapping insulation layers. These features ensure a secure, well-insulated, and robust environment for the cells while offering a stable framework for electrical balancing.

FIG. 2A is a Perspective View of AC Battery Storage Grid provides an angled perspective of an AC battery storage grid. This grid consists of a 4×7 arrangement of aluminium tubes, organized in a way that allows a stepwise AC voltage. Important features include the switching locations for generating stepwise voltage, the interconnections to the compensator, and the compact dimensions of the system. The figure shows how the grid can transform stored DC power into usable AC output, and the function of the compensator in creating a suitable sine wave for use.

FIG. 2B is a Perspective View of DC Battery Storage Grid showcases a DC battery storage grid similar to the AC grid in FIG. 2A, but designed for producing a DC voltage for an inverter. Key features displayed include the interconnections between cell banks, the flying capacitors for balancing, and the DC output arrangement to an inverter. This figure emphasizes the flexibility of the system in offering different electrical configurations and demonstrates the role of the inverter in converting high-voltage DC output into AC power.

FIG. 3 is a Alternative Tube Configuration for Quadruple Cell Storage depicts an alternate tube configuration, showing a squarer design with rounded corners that accommodates four cells, doubling the storage capacity per tube of the design in FIG. 1. Key features include increased redundancy, reduced balancing components due to the parallel connections at each layer, and the use of fusible links to ensure system safety and reliability. Despite the heightened storage capacity and redundancy, the configuration manages potential risks, such as excessive current or arc flash, effectively.

FIG. 4A is a Perspective View of Quadruple Cell AC Battery Storage Grid presents a 3D, top-down view of a grid layout using the modified tube design from FIG. 3 to generate stepwise AC voltage. This layout demonstrates the transformation from stored DC power to usable AC output through marked switching locations. The figure also shows the interconnections to the compensator, which is crucial for converting stepwise AC into a sine wave suitable for use. Despite an increase in storage capacity, the system retains a compact design with the same dimensions as the previous design. This more compact arrangement increases storage capacity compared with FIGS. 2A and 2B.

FIG. 4B is a Perspective View of Quadruple Cell DC Battery Storage Grid mirrors FIG. 4A but aligns with a DC electrical configuration designed for producing DC voltage for an inverter. This grid configuration showcases the interconnections between cell banks, the flying capacitors for balancing, and the high-voltage DC output's arrangement to the inverter. As in FIG. 4A, the system design maintains compact dimensions and layout, displaying the modified aluminum tubes that accommodate the quadruple cell configuration. With increased storage, it manages to fit approximately 14% more energy storage in the same volume.

FIG. 5 is a Side View of Dual Tube Configuration displays a side view of the dual tube battery storage system, where cells and balancing and monitoring boards are housed within the structure. Key features include coach bolts, which secure the Printed Circuit Board (PCB), cells and edge connectors, the balancing and monitoring boards (BMS) with bronze terminals for electrical connections, and a spring-loaded insert at the end of the tube featuring a PCB fuse plate. This figure delivers a thorough overview of the dual tube configuration, showing the importance of each component and its role in the system.

FIG. 6 is a Schematic of PCB Arrangement for a Stepwise Sine Wave Approximation presents a schematic layout of the PCB designed for generating a [symbol] stepwise approximation of a sine waveform, primarily using N-channel MOSFETs.

Notable aspects include copper protection to prevent board damage due to cell shorting events, reference voltage for MOSFET drivers to prevent unwanted switching, multiple 100V switching MOSFETs wired in parallel to lower switching resistance, and connectors for Battery Management System (BMS) PCB strings.

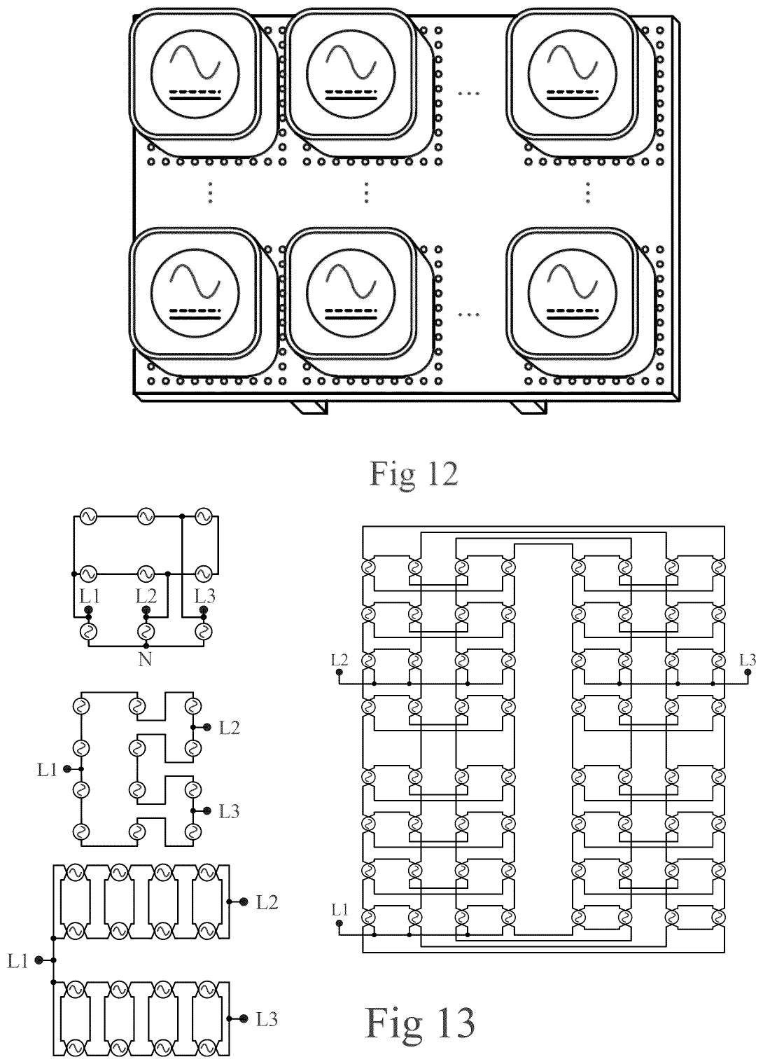

The schematic also highlights the presence of an ‘optimiser’ which has dual functionality: it controls the energy storage cells to produce the approximation with high power conversion efficiency and works with the compensator to manage the switching timing for the charging and discharging cycle. Overall, FIG. 6 offers a comprehensive blueprint of the PCB design and its integral role in the energy storage system.

FIG. 7 is a Schematic of PCB Arrangement for High Voltage DC for Inverter Use illustrates the PCB arrangement designed for a flying capacitor balancer, intended to balance series-connected strings of cells. Noteworthy features include copper protection to ensure safety against cell shorting, cell strings and balancing capacitors with Positive Temperature Coefficient (PTC) thermal fuse for current limitation, voltage monitoring to adjust the switching frequency, and 28 connectors for Battery Management System (BMS) PCB strings. The figure exemplifies efficient design practices to enhance system safety and reliability, showing how all interconnection paths run through the PCB, eliminating the need for external wiring.

FIG. 8 is a Schematic Diagram of Switching Mechanism for Connecting Cells to a Mux Channel provides a detailed depiction of the switching mechanism employed to connect cell terminals to a multiplexer (mux) channel. Major elements include a Resistor-Capacitor pair (Item 25) that controls the state of the mux's MOSFETs, Desaturation NPN Transistors (Item 26) designed to prevent potential damage from voltage spikes or excess mux current, Series Reverse Emitter Base Junctions (Item 27) that enable the mux to remain ON for an extended period, a dual channel for accessing a single cell, and a shutdown mechanism to conserve power. The figure highlights the complexity of the switching mechanism and the importance of each component in managing the connection of cells to a mux channel in a robust, overload-protected way.

FIG. 9 is a Schematic Diagram of Shielding and Earthing Arrangement for Energy Storage Pillar provides an insightful look into the shielding and earthing arrangements of an energy storage pillar. This setup is pivotal in maintaining the safety and electromagnetic compatibility (EMC) standards of the pillar. Key elements include a two-wire connection (L1 and L2), secondary common mode choke (Item 30) for EMI suppression, direct connection of L1 to the shield (Item 31) for a common point, main common mode choke and filter (Item 32) for high-frequency noise suppression, comprehensive shielding of compensator and optimiser PCBs (Item 33), shield plate (Item 35) affixed inside the cover, and metal spring covers at the base for EMC shielding and structural safety.

FIG. 10 is a Detailed Design of the Bottom Injection Molded Cover and Spring Cover offers a detailed depiction of the bottom injection molded cover and spring covers. These components, critical to the overall safety and functionality of the energy storage pillar, ensure a reliable interconnection of cells and facilitate cell installation and removal. Important elements include the double seal (Item 36) for protection against water intrusion, openings for cell insertion (Item 37), screw holes (Item 38) for securing the tubes, spring clips (Item 11) for locking the spring covers, and durable, corrosion-resistant spring covers (Item 12) which provide an efficient shield. The figure underscores the thoughtfulness behind each design decision, reflecting an emphasis on protection, accessibility, and efficient shielding.

FIG. 11 is a Detailed View of the Base Region of the Energy Storage Pillar provides a meticulous breakdown of the design and construction of the base region of the energy storage pillar, underscoring the essential features that contribute to the system's stability, ease of accessibility, and protective measures. The design showcases a sturdy base plate (Item 40), designed for versatile installation options, complemented by stainless steel pins (Item 42) that ensure system stability while doubling as functional hinges for convenient access. The design also incorporates clear cell access openings, a specialized recess in the base plate (Item 44) that accommodates an expanded foam seal to protect against intrusion, and an application of extruded polycarbonate reinforced insulation (Item 45) to bolster the overall strength and durability of the system.

FIG. 12 is a Design of Plug-and-Play Pillars and Pallets provides a comprehensive exploration of the plug-and-play characteristics of pillars and pallets within the energy storage system. The design considerations encompass a cross-brace or locking arrangement for improved stability and system reliability, under-pallet airflow and vents for optimal heat management, plug and play interconnection promoting efficient energy transfer and redundancy, quick-release connections simplifying system installation and maintenance, space for standard forklift prongs enhancing system mobility, lifting points on pillars allowing for easy pillar replacement, and a standard size that fits neatly into a 10-foot high cube shipping container. The elements of this design underline the system's ease of installation, mobility, and maintenance.

FIG. 13 is a Wiring Arrangements for Pillar-Based Energy Storage System thoroughly illustrates the possible wiring configurations for a pillar-based energy storage system, emphasizing its flexibility, autonomous self-organization abilities, and various layout options for achieving differing levels of redundancy and voltage requirements. The layouts include a 3×3 pillar pallet (top left) representing a typical star/delta 240V_{ac} system with redundant loops, a 4×3 pillar pallet (middle left) exemplifying a delta 1000V_{ac} system with a single redundancy loop, a 4×4 pillar pallet (bottom left) showcasing a delta 1000V_{ac} system with side-by-side parallel pillar loops, and a 4×4 pillar pallet with 2×2 pallets in a 10-foot shipping container (right) depicting a delta 1000V_{ac} system with multilayer redundancy. Notably, the software managing the system assists in charge distribution by subtly modulating the voltages to control respective current flows across the pillars.

The system also incorporates stress-testing capabilities for connections either before commissioning or during maintenance. This detailed figure underscores the system's adaptability and resilience, capable of fulfilling diverse operational requirements.

### DESCRIPTION OF THE INVENTION

Referring to the Figures, there is shown an energy storage system for use either connected to the main electricity grid (on-grid) or independently of it (off-grid).

This invention expands upon the concepts presented in previous patents, including:
1. WO2015184512A1 “POWER CONVERSION METHOD AND SYSTEM”,
2. WO2015184511A1 “SYSTEM AND METHOD FOR DETECTING CONNECTOR FAULTS IN POWER CONVERSION SYSTEM”,
3. WO2016008003A1 “METHOD FOR CONTROLLING A POWER CONVERSION SYSTEM”, and
4. WO2019113647A1 “BATTERY PACK”

These aforementioned patents are hereby incorporated by reference. This invention introduces several layers of additional functionality and utility, enhancing the earlier patents in significant ways:
1. The energy storage system presented herein boasts a high-capacity design with improved Electromagnetic Interference (EMI) and Electromagnetic Compatibility (EMC) compliance. It also offers simplified cell replacement and installation compared to the previously described battery pack. These improvements are brought to life by the features outlined in the claims and descriptions that follow.
2. The invention proposes a system with series and parallel connections, offering enhanced redundancy as well as commercial and utility storage options. The specifics of this design are detailed in the subsequent claims and descriptions.
3. This energy storage system also provides improved surge protection and testing capabilities compared to previous systems. The specifics of these enhancements are outlined in the forthcoming claims and descriptions.

Our initial point of invention is the energy storage system which is the crux of this invention. This system comprises a plurality of elongated compartments, each designed to house a string of energy storage cells. Each compartment is equipped with accessible openings, specifically engineered to facilitate the easy installation and removal of these storage cells.

These compartments have been structured to accommodate two or more storage cells, arranged adjacently within their confines. Additionally, the system incorporates a retaining mechanism that holds the string of cells firmly pressed together.

This arrangement ensures a reliable current path, forming the backbone of our energy storage system.

Furthermore, this system integrates a sophisticated balancing mechanism. This mechanism features a balancing system, inclusive of electrical tabs that connect to the junctions of adjacent cells. The mechanism also possesses means to shift charge into or out of these tabs. This enables the charging or discharging of cells, thereby harmonizing their voltages. This complex yet efficient process enables long strings of cells to be balanced without resorting to complex wiring.

Subsequent sections will further elaborate on the detailed aspects of this invention, along with the specifics of its operation, installation, and the benefits.

Features are added according to the figured descriptions of the system that follows, which describes the best-known embodiment as a non-limiting example:

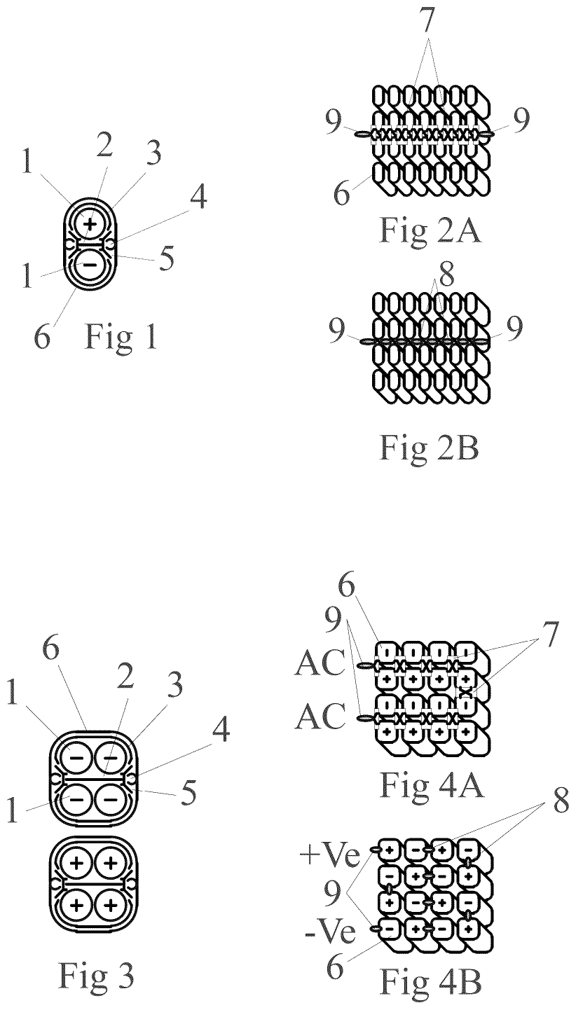

### FIG. 1: Top View of Extruded Aluminium Tube for Battery Storage

FIG. 1 offers a bird's-eye view of an extruded aluminium tube, which is specifically designed to accommodate battery storage. The layout and features demonstrated in this diagram provide insights into how this setup supports the efficient operation and safety of the battery system.

### Key Elements of FIG. 1

Battery Cells and PCB: The tube is designed to hold two battery cells (Item 1) side by side. These cells are separated by a Printed Circuit Board (PCB) (Item 2) that is responsible for the electrical balancing of the battery system.
Extruded Screw Holes: The design incorporates extruded screw holes (Item 4), which facilitate secure attachment to an injection-molded cap. These screw holes are integral for maintaining structural integrity and ensuring a rigid fit.
Insulation: A notable feature of the tube design is the provision of a second, double insulation (Item 3) between the cells and the tube. This additional safety measure provides a robust barrier that mitigates the risk of electrical interference or shock. The additional layer of insulation also guards against corrosion and cells having poor quality or damaged shrink wrap.
PCB Clamps: The layout also includes PCB clamps, strategically positioned to provide support to the PCB while enhancing insulation. These clamps not only maintain the PCB's position but also ensure its safety.
Overlapping Insulation Layers: Above all, overlapping layers (items 3 and 5) of insulation are installed to further enhance safety standards. This layer is particularly crucial in preserving creepage distances—the shortest path between two conductive parts, or between a conductive part and the bounding surface of the equipment, measured along the surface of the insulation.

The layout illustrated in FIG. 1 provides a comprehensive overview of the intricate design of the extruded aluminium tube, indicating the thoughtfulness behind the tube's design, particularly in terms of ensuring the safety and utility of the battery storage system.

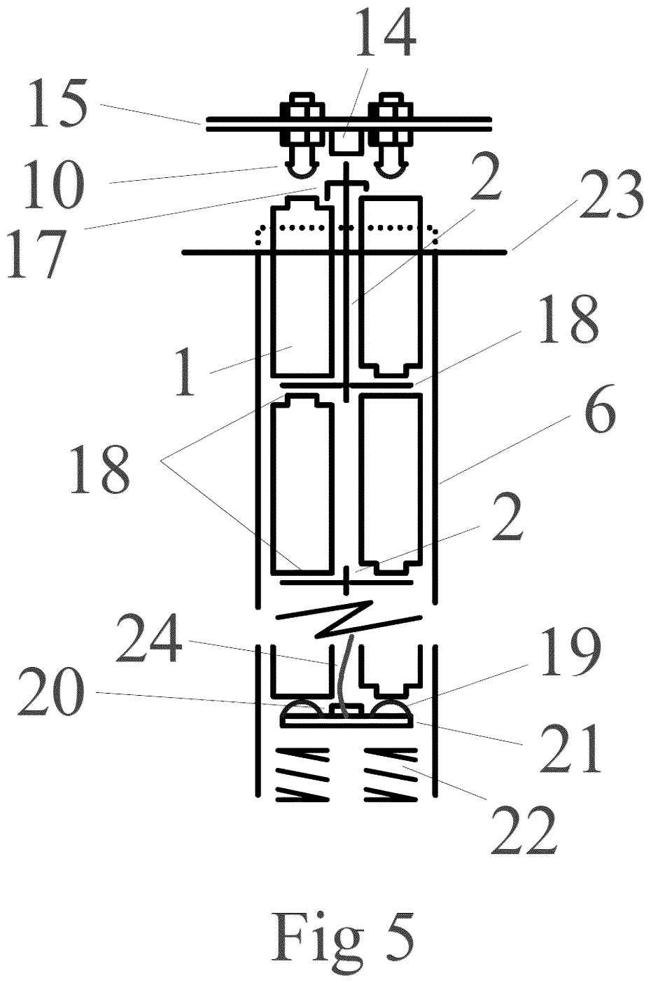

### FIG. 2A: Perspective View of AC Battery Storage Grid

FIG. 2A offers an off-axis, top-down perspective of the organized grid structure, showing the efficient utilization of extruded aluminium tubes. The figure illustrates a 4×7 grid arrangement housing 28 tubes and aligns with schematic diagrams (FIG. 6) that elaborate on the electrical arrangement for producing a stepwise AC voltage.

### Key Elements of FIG. 2A

Stepping between Battery Banks: (Item 7) points to the switching locations for generating the stepwise voltage, marking the transformation from the stored DC power to a utilizable AC output. As can be seen, stepping is transverse to the layout of the battery banks. Taking the left (Item 9) as 0V, with series cells in tubes having 72V each, the output voltage at the right (Item 9) can range from −504V to +504V.
Interconnections to the Compensator (Item 9): This feature visualizes where the interconnections to the compensator, situated on the subsequent PCB, are positioned. The compensator is an essential component that converts the stepwise AC into a sine wave that is fit for use, regulating and modulating voltage levels in tandem with the stepwise mechanisms, thereby ensuring power system compatibility.
Dimensions and Structure: The system, inclusive of injection-molded end caps, is approximately 1900 mm in height, 300 mm in width, and 300 mm in depth, emphasizing the system's compactness despite containing numerous battery compartments. The figure exhibits the extruded aluminium tubes (Item 6) that can accommodate battery cells and their associated PCBs for a complete AC system.

### FIG. 2B: Perspective View of DC Battery Storage Grid

Parallel to FIG. 2A, FIG. 2B aligns with a DC electrical configuration (FIG. 7), displaying an identical grid arrangement of battery storage compartments, but a High Voltage (HV) system engineered for generating DC voltage for use by an inverter.

### Key Elements of FIG. 2B

Interconnections between Battery Banks (Item 8): The figure demonstrates where the interconnections between cell banks and the location of the flying capacitors for balancing are electrically situated on the PCB. This also exhibits the interconnection transverse to the layout of the paralleled battery banks.
DC Output Arrangement to an Inverter: (Item 9) signifies where the interconnections to the inverter on the ensuing PCB are situated. The inverter plays a critical role in converting the high-voltage DC output into AC power.
Dimensions and Structure: Consistent with FIG. 2A, FIG. 2B exhibits the same compact dimensions and layout. The extruded aluminium tubes (Item 6) are also represented, showing the system's storage capacity and its well-structured design.

Collectively, FIGS. 2A and 2B offer a comprehensive overview of the various electrical configurations feasible with this battery storage system, highlighting its flexibility in power output and system design, and possible I/O arrangements.

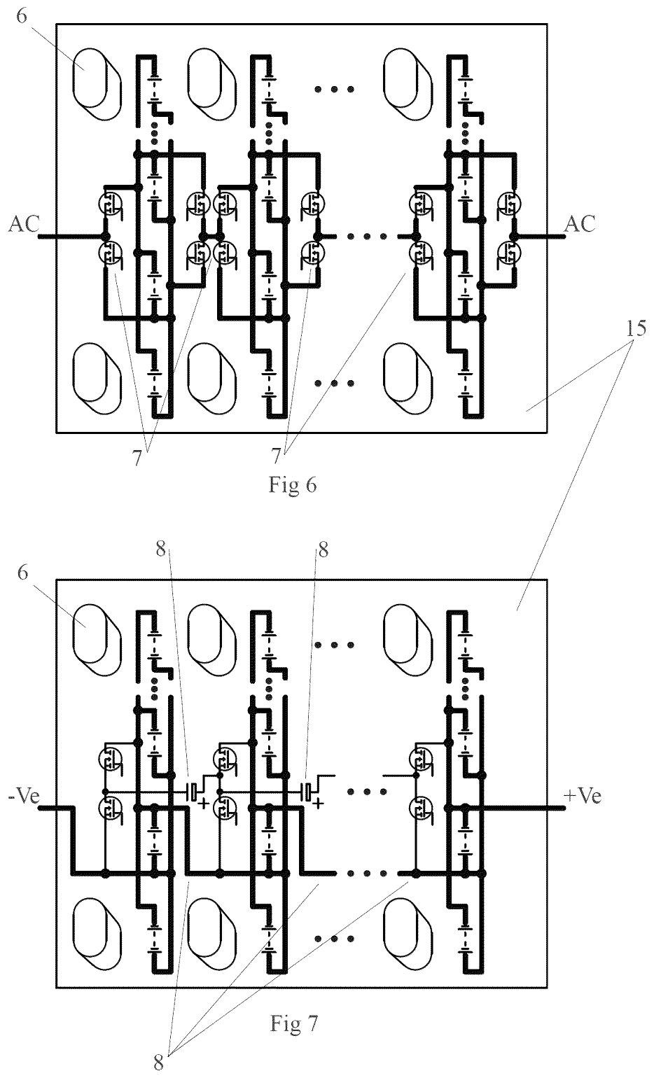

### FIG. 3: Alternative Tube Configuration for Quadruple Cell Storage

FIG. 3 introduces an alternative to the arrangement outlined in FIG. 1, demonstrating a tube with a more square-like structure and rounded corners designed to house the cells. Unlike the two-cell housing of FIG. 1, this tube is devised to accommodate four cells.

### Key Elements of FIG. 3

Quadruple Cell Housing: This configuration houses layers of four cells within the tube, effectively doubling the storage capacity compared to FIG. 1's two-cell layers tube layout. This design simplifies the redundancy mechanism, moving from a software-driven process that balances cells within four double tubes in parallel (shown 4x double tubes vertically in FIG. 2A) to a mechanism where redundancy is achieved through quad parallel cells that have fusible links to the balancing PCBs.
Balancing Component Reduction: The identical orientation of the four cells facilitates parallel connections at each layer, leading to a significant decrease in the number of balancing components required. The configuration—with four cells in parallel and twelve in series (24 cells total, considering a return path)—generates a nominal voltage akin to that in FIG. 1 but offers enhanced redundancy and nearly quarters the number of balancing components.
Risk Management: Despite the enhanced storage capacity and redundancy, this configuration introduces potential risks such as excessive current or arc flash due to parallel cells at each layer. Risk of dead short circuits are mitigated by fusible links.
Fusible Links: The cell connection points are equipped with fusible links leading to the BMS PCBs, as the links must only carry balancing currents, the fusible links can be relatively high resistance without appreciable loss of efficiency. Unlike through-current fuses that necessitate minimal resistance for efficient operation and heat reduction, these links encounter relatively high currents only during abnormal events. Thus, their higher resistance level and lower current capacity are suitable and contribute to overall system safety and reliability.
Consistency with FIG. 1: Apart from the above alterations, the layout and components in FIG. 3 largely align with those depicted in FIG. 1.

In presenting this alternative configuration, FIG. 3 highlights a design that simplifies energy storage replacement, enhances redundancy, reduces the quantity of balancing components, and effectively manages associated risks. This flexible design avoids imposing a reliance on a particular power conversion method, thereby permitting an adaptable system configuration based on specific needs.

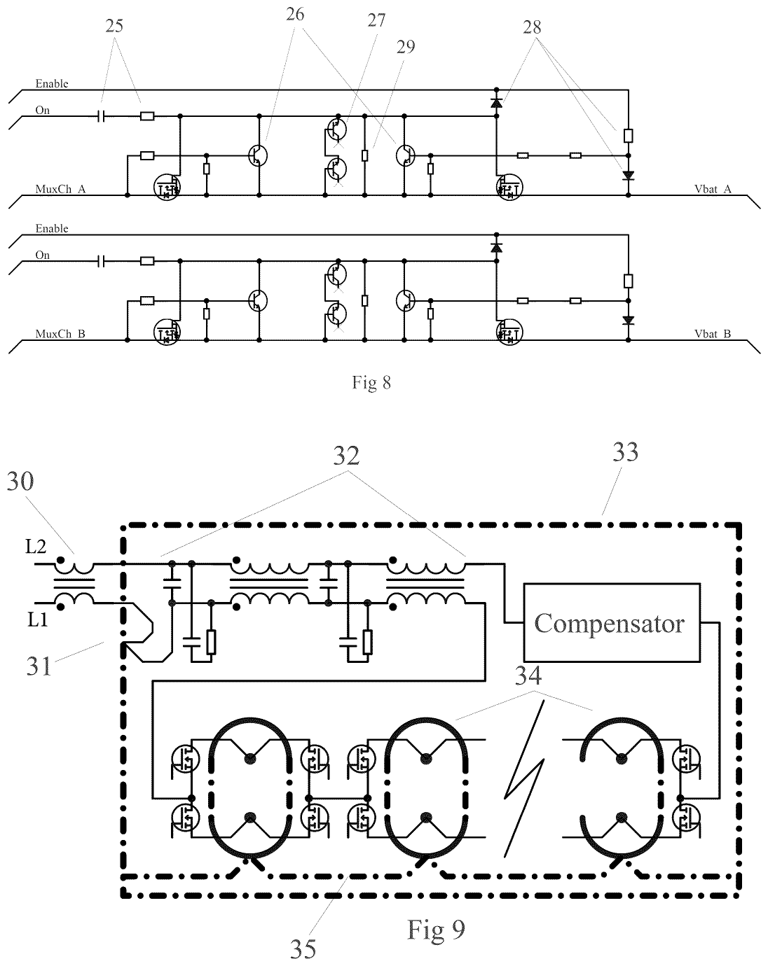

### FIG. 4A: Perspective View of Quadruple Cell AC Battery Storage Grid

FIG. 4A, like FIG. 2A, provides an off-axis, top-down perspective view of the grid layout. However, this figure features a modified tube design, specifically designed to accommodate four battery cells, conforming with the schematic diagrams (FIG. 6) for generating a stepwise AC voltage.

### Key Elements of FIG. 4A

AC Output Arrangement: The switching locations for generating the stepwise voltage are marked as (Item 7). This highlights the transformation process from the stored DC power within the quadruple cells to usable AC output. Storage density is increased slightly with this arrangement, enabling one additional switching layer that enables from −576V to +576V stepped across the terminals (Item 9) with 72V per two tubes of cells.
Interconnections to the Compensator (Item 9): The figure illustrates where the interconnections to the compensator on the next PCB are located. The compensator is a critical component that converts the stepwise AC into a sine wave suitable for use, managing and adjusting the voltage levels in coordination with the stepwise means, and ensuring power system compatibility. The compensator can be either an active device, as mentioned in the related patent, or a passive inductor that forms PWM as needed to produce the desired quality of sine wave.
Dimensions and Structure: Like FIG. 2A, the dimensions of this system, inclusive of the injection-molded end caps, are approximately 1900 mm in height, 300 mm in width, and 300 mm in depth. Despite the increased storage capacity with the inclusion of quadruple cells, the system maintains a compact structure. The figure also depicts the modified aluminum tubes (Item 6) that can house the quadruple cells and their corresponding PCBs.
Storage Capacity: This arrangement fits roughly 14% more storage in the same volume.

### FIG. 4B: Perspective View of Quadruple Cell DC Battery Storage Grid

FIG. 4B aligns with a DC electrical configuration, much like FIG. 2B. It showcases the grid arrangement of quadruple cell battery storage compartments, indicating a system designed for generating DC voltage for use by an inverter.

### Key Elements of FIG. 4B

Interconnections to the Inverter (Item 8): This feature demonstrates where the interconnections between cell banks and the location of the flying capacitors for balancing are electrically located on the PCB.
DC Output Arrangement: (Item 9) points to the interconnections to the inverter on the subsequent PCB. The inverter is crucial in converting the high-voltage DC output from the quadruple cell configuration into AC power.
Dimensions and Structure: As in FIG. 4A, FIG. 4B displays the same compact dimensions and layout, with the modified aluminum tubes (Item 6) that can accommodate the quadruple cell configuration.
Storage Capacity: This arrangement fits roughly 14% more storage in the same volume.

Together, FIGS. 4A and 4B provide a comprehensive overview of the different electrical arrangements possible with this quadruple cell battery storage system.

They show the potential for enhanced voltage output, storage capacity and system design flexibility while indicating possible terminal polarities.

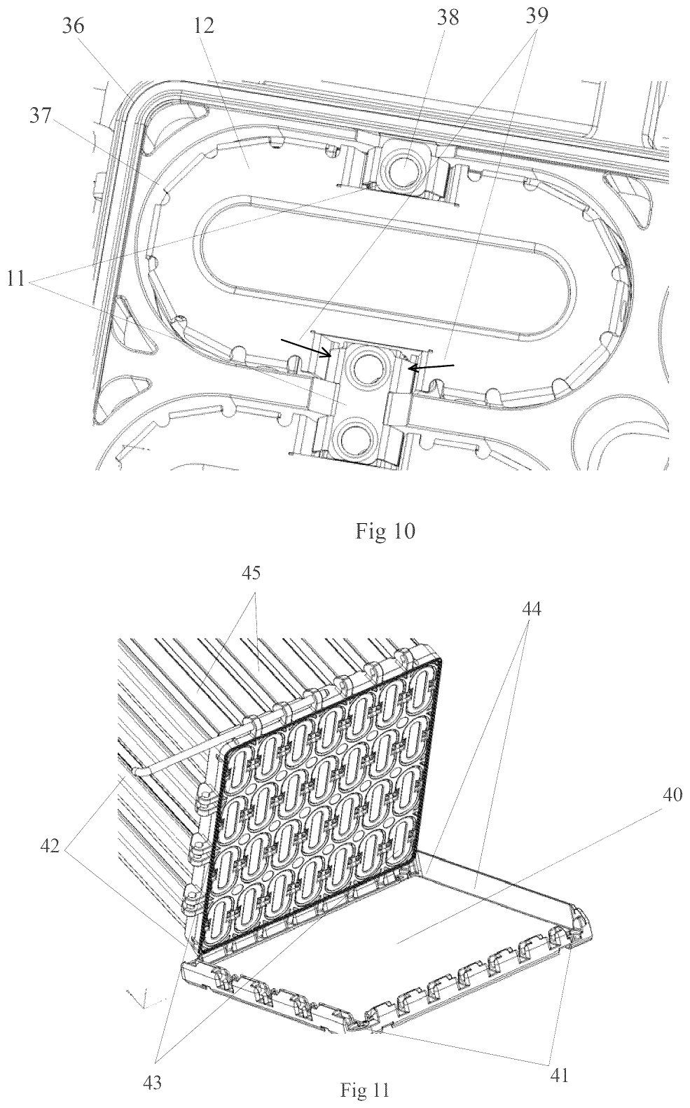

### FIG. 5: Side View of Dual Tube Configuration

FIG. 5 provides a side view of the dual tube configuration used in the battery storage system. At the top of this configuration, there's an injection-molded cover that attaches to all 28 tubes. The cover itself is not pictured in this figure, but its bottom edge is marked as (Item 23).

### Key Elements of FIG. 5

Coach Bolts and PCB: Coach bolts (Item 10) bolted to the cover can be seen in the figure. Held in place by their corresponding nuts, these bolts secure the Printed Circuit Board (PCB, (Item 15)) via star or split washers, which are further clamped by a second set of associated nuts.
Cells and Connectors: The figure depicts cells (Item 1) along with card edge connectors (Item 14) that hold the balancing and monitoring boards (Item 2). The balancing and monitoring boards are firmly pressed into the edge connector by an injection-molded pressure plate (Item 17). The pressure plate is pushed by the top cell, which in turn pushes the PCB into the connector.
Balancing and Monitoring Boards (BMS): The balancing and monitoring board (Item 2) comprises multiple segments, each featuring electrical phosphor bronze terminals for electrically connecting to the junction points between cells. Each segment is responsible for monitoring and balancing each end of adjacent cells. Additionally, a flexible joiner spans across subsequent cells before connecting to the next BMS segment.
Spring-Loaded Insert and Fuse Plate: Located at the end of the tube is a spring-loaded insert. This insert (not shown), made of injection-molded material, features a PCB fuse plate (Item 21) that connects the ends of the cells. Diagrammatic representations of springs are shown as (Item 22), terminals as (Item 19), and the fuse as (Item 20). The fuse can be installed after cells are installed and tested to ensure polarity. The fuse electrically connects across the ends of the cells, protecting the cells against excess current that may result from system damage or failure.

FIG. 5 delivers a comprehensive look at the dual tube configuration, detailing critical components and their placement within the system. It helps in understanding the electrical connections, the mechanical setup, and each component's role in the overall system.

### FIG. 6: Schematic of PCB Arrangement for a Stepwise Sine Wave Approximation

FIG. 6 presents a schematic diagram illustrating the PCB's layout, specifically designed for generating a stepwise approximation of a sine waveform. The arrangement primarily uses N-channel MOSFETs (Metal-Oxide-Semiconductor Field-Effect-Transistors), with their drains connected to positive connections of cells of four dual tubes as portrayed in FIGS. 1 and 2A and shown in the drawing using standard battery symbols having the positive short segment at the top.

### Key Elements of FIG. 6:

Copper Protection: The PCB incorporates ample copper to ensure that a cell shorting event will trigger the fuse (depicted in FIG. 5) before causing any damage to the board itself due to current flowing in the positive and negative vertical schematic lines.
Reference Voltage for Drivers: The drivers for all connected MOSFETs, including those used for balancing within the tubes, are referenced to their own power supply to prevent unwanted switching caused by 0V currents. The sources of the MOSFETS connect to the negatives of the cell strings while their drivers connected to the 0V of related microprocessor supply.
Parallel Switching MOSFETs: The schematic includes multiple 100V switching MOSFETs wired and driven in parallel. This configuration lowers switching resistance and reduces overall losses. This arrangement improves reliability by removing the need for external wiring as all interconnection paths are incorporated into the PCB.
Connectors for BMS PCB Strings: The PCB features 28 connectors for Battery Management System (BMS) PCB strings. Each string corresponds to a dual tube, following the configuration depicted in FIG. 2A. Conversely, if the design follows FIG. 4A, the routing would differ, and there would be 16 connectors instead.

Not shown in the figure, the PCB communicates with the controlling compensator of the system and adjusts under its control to produce an approximation of a mains waveform. This device is termed an ‘optimiser’ due to its dual functionality:
The optimiser controls the energy storage cells, switching them to produce the approximation with an exceedingly high power conversion efficiency. The slow switching frequency only results in nominal power wastage, while the combined series resistance of all MOSFETs, in this case, 3.5 mΩ devices with four in parallel, yields less than 2 mΩ per switching H bridge. This results in less than 14 mΩ across all seven optimiser banks of cells. Hence, losses at 20 A and 240Vᵣₘₛ are less than 0.1%. This extremely high efficiency results in commensurately low heat dissipation and ability to operate with passive cooling. A small recirculating fan is installed inside the cavity that housed the optimiser and compensator boards. This fan is operates at high power levels and avoids any need for vents in the case.
The compensator governs the switching timing, maintaining cell banks with a higher charge level in series for a longer duration while discharging and vice versa during the charging cycle.

In summary, FIG. 6 provides a comprehensive schematic of the PCB's design and interconnectivity. It emphasizes how the PCB, MOSFETs, and other components collaborate to form a stepwise approximation of a sine waveform, demonstrating effective design choices that manage electrical flow and minimize losses, making it a desirable part of the energy storage system.

### FIG. 7: Schematic of PCB Arrangement for High Voltage DC for Inverter Use

FIG. 7 is a schematic diagram illustrating the PCB's arrangement for balancing series-connected strings of cells using a topology commonly referred to as a flying capacitor balancer. This configuration produces high voltage DC power, intended for use by an inverter. In this design, N-channel MOSFETs are used, with drains connected to the cells of four dual tubes, consistent with the style in FIGS. 1 and 2B.

### Key Elements of FIG. 7

Copper Protection: The PCB features enough copper to ensure that if a cell shorts, the fuse (as seen in FIG. 5) blows before the board gets damaged due to current flowing through the positive and negative vertical lines.
Reference Voltage for Drivers: The drivers for all connected MOSFETs, including those used for balancing within the tubes, are referenced to their own power supply to prevent unwanted switching caused by 0V currents. The sources of the MOSFETS connect to the negatives of the cell strings while their drivers connected to the 0V of related microprocessor supply.
Cell Strings and Balancing Capacitors: Cell strings are series-connected, and electrolytic capacitors for balancing are connected as shown by (Item 8).

A Positive Temperature Coefficient (PTC) thermal fuse is placed in series with the capacitors to limit current. An inductor, tuned to the switching frequency, can be wired in series with the capacitor, enabling the use of a lower value smaller capacitor, and thus, allowing the option for a film or ceramic capacitor.
Voltage Monitoring: Monitoring of string voltages is provided and results in the switching frequency being adjusted to limit the average current according to the voltage difference across the strings. Power moved through the flying capacitor is proportional to the switching frequency in a non-tuned system so the flying capacitor switching period is adjusted in proportion to the voltage difference between the highest and lowest measured string voltage. If an inductor is used then the frequency alters according to a calculated formula that takes into account the Q factor of the resonant circuit.
Connectors for BMS PCB Strings: The PCB has 28 connectors for Battery Management System (BMS) PCB strings, with one string per dual tube in alignment with the FIG. 2B arrangement. If the arrangement from FIG. 4B were followed, the routing would be different and there would be 16 connectors instead.
No External Wiring: All interconnection paths run through the PCB, obviating the need for external wiring.

Overall, FIG. 7 provides a clear depiction of the PCB's arrangement for generating high voltage DC power for inverter use. This arrangement effectively manages the balancing of cells, current limitations, and voltage monitoring. It demonstrates how efficient design choices can simplify construction and operation while enhancing the system's safety and reliability.

### FIG. 8: Schematic Diagram of Switching Mechanism for Connecting Cells to a Mux Channel

FIG. 8 depicts a schematic diagram that details the switching mechanism used to connect cell terminals to a multiplexer (mux) channel. This diagram reveals the complex interplay of various components that create a low-tech four-wire control mechanism, enabling an efficient, overload-protected switching mechanism that supports replaceable cells on a large-scale energy storage system. Switching regulators driving MuxChA and MuxChB channels and precision ADCs monitoring voltages on these lines are not depicted. The selection of a mux channel, connecting it to a cell connection point, involves the associated regulator being driven to a voltage proximate to the expected cell voltage, then connecting to the nearest cell mux upon command.

### Key Elements of FIG. 8

Resistor-Capacitor Pair (Item 25): This pair consists of a resistor, which serves to limit the current, and a capacitor, which blocks the voltage difference between the driver that toggles the state of the mux's MOSFETs (Metal-OxideSemiconductor Field-Effect Transistors). The driver alternates between high and low states, thus turning the selected mux ON or OFF, respectively.
Desaturation NPN Transistors (Item 26): These transistors are designed to prevent a mux from turning ON when the voltage of its connected cell isn't within the common mux potential's range and to disable the MOSFETs if the differential between the cell voltage and the mux channel voltage exceeds the voltage set by the desaturation sense resistors connected to these transistor bases. This feature allows initial connection to the nearest cell and prevents potential damage from voltage spikes or excess mux current. This desaturation mechanism ensures that any connection is bistable; a cell closer to the mux potential turns on more powerfully, drawing the mux voltage away from another cell voltage, leading the latter to desaturate and further turn off.
Series Reverse Emitter Base Junctions (Item 27): These transistors exhibit a sharp knee current at around 5V with very low leakage due to their series reverse emitter base junctions, which standard zener diodes don't achieve at a voltage close to their turn ON point. This characteristic enables the mux to remain ON for a significant period before requiring to be turned OFF and ON again, thus recharging the blocking capacitor (Item 25).
Dual Channel: The diagram features two circuit copies, shown top and bottom, which connect to the even and odd cell positive terminals (odd and even negative terminals of series-connected cells), respectively. This design has dual purposes:
Mux channels are spaced at least 5V apart (two cells at minimum charge of 2.5V), facilitating an easy 2.5V desaturation voltage to be achieved using the base resistor divider.
A single cell can be accessed for charging or discharging, with one mux channel connecting to its positive terminal and the other to its negative terminal.
Shutdown Mechanism: All muxes can be sent into a deep sleep state to conserve power. This is achieved by setting the switching regulators that drive the mux channels to a low voltage and then setting the enable to a low state. The resistor (Item 29) ensures gates cannot float high while enabled.

In summary, FIG. 8 offers a detailed portrayal of the switching mechanism, emphasizing the integral role of each component in smoothly connecting cells to a mux channel. The diagram underscores the complexity of the switching mechanism and the significance of each element in securing both control via the two control lines and unique cell connection mechanism.

### FIG. 9: Schematic Diagram of Shielding and Earthing Arrangement for Energy Storage Pillar

FIG. 9 provides a detailed illustration of the shielding and earthing arrangement employed in an energy storage pillar. This assembly is critical in maintaining both the safe operation of the energy storage pillar and compliance with electromagnetic compatibility (EMC) standards.

### Key Elements of FIG. 9

Two-Wire Connection (L1 and L2): The figure depicts a two-wire connection, labeled L1 and L2. L1 can be a line voltage or functional earth or [symbol] neutral.
Secondary Common Mode Choke (Item 30): Positioned on the lead at the point of entry, the secondary common mode choke works to suppress conducted electromagnetic interference (EMI) by reducing common mode noise current.
Direct Connection of L1 to the Shield (Item 31): L1 is directly connected to the shield near or at the cable entry point, establishing a common point that can be wired as a functional earth.
Main Common Mode Choke and Filter (Item 32): This component is installed to suppress high-frequency noise within the system, leading to the electronics.
Shielding of Compensator and Optimiser PCBs (Item 33): A comprehensive shield covers the compensator and optimiser Printed Circuit Boards (PCBs) located at the top of the pillar, offering protection and facilitating EMC compliance.
Shield Plate (Item 35): Either a PCB or a solid metal shield plate is affixed inside the injection-molded cover. This shield is screwed down onto the aluminium tube shields (Items 35), creating an electrical interconnection and integrating the aluminium tubes into the shielding arrangement.
Metal Spring Covers at the Base: At the base of the pillar, metal spring covers are electrically linked to each other through retaining clips (item 11 of FIG. 10). These clips mechanically and electrically connect the lower ends of the aluminium tubes, which possess electrical stepping inside. This 5 arrangement prevents differential voltages at these ends, mitigating potential EMC issues arising from such voltages. This setup provides EMC shielding benefits for the arrangement shown in FIG. 6, although not of significant benefit for FIG. 7. These shields also serve a safety function, maintaining the structural integrity of the system in case of a failure that leads to a cell [symbol] overheating scenario.

Overall, FIG. 9 provides a comprehensive insight into the intricate shielding and earthing setup within the energy storage pillar, underlining its contribution to both safety and EMC compliance.

### FIG. 10: Detailed Design of the Bottom Injection Molded Cover and Spring Cover

FIG. 10 provides an in-depth look at the design and functionality of the bottom injection molded cover and spring covers. These critical components serve to secure the cells within the energy storage pillar, provides protection, force on the cells to ensure reliable interconnection and facilitate the process of cell installation and removal.

### Key Elements of FIG. 10

Double Seal (Item 36): The bottom injection molded cover prominently features a double seal around its periphery. This seal plays a crucial role in safeguarding against water intrusion when the pillar is in an upright position, effectively sealing the cell loading area.
Openings for Cell Insertion (Item 37): The cover design includes multiple openings, aligned with the internal dimensions of the tubes. These portals facilitate the process of cell insertion and removal.
Screw Holes (Item 38): Integrated into the cover are holes strategically positioned to match the screw slots of the tubes. Screws inserted through these holes securely affix the tubes to the molded cover, ensuring a robust connection.
Spring Clips (Item 11): Mounted over the screw holes are U-shaped spring clips, held in place by the same screws used to fasten the tubes. These clips feature wings that lock the spring covers (Item 12) in place. The clips can be squeezed shut (Item 39) to facilitate the removal of the spring covers.
Spring Covers (Item 12): The spring covers and clips are made from stainless steel, chosen for its durability, strength and resistance to corrosion. Their electrical conductivity also provides an efficient shield across the bottom of the pillar.

In summary, FIG. 10 presents a detailed view into of the design considerations within the energy storage system, particularly the construction of the bottom cover.

It highlights the measures taken to ensure the protection, accessibility, and shielding of the cells within the system.

### FIG. 11: Design of the Base Region of the Energy Storage Pillar

FIG. 11 provides an in-depth look at the practical implementation of the base region of the energy storage pillar. This depiction showcases the functional elements that ensure stability, ease of accessibility, and protective shielding of the system.

### Key Elements of FIG. 11

Base Plate (Item 40): Central to the design is the base plate, which can be secured to a floor using designated screw holes (Item 41). Alternative or additional attachment methods, such as permanent adhesives like liquid nails or a two-part epoxy, provide flexibility in the installation process.
Stainless Steel Pins (Item 42): Embedded within the design are stainless steel pins serving dual functions. Firstly, they help retain the pillar in an upright position, thus ensuring stability. Secondly, they function as hinges on any one of three axes (left, front, or right), allowing the pillar to lean over for easy access to the cells. Not shown is an additional stabilising wall plate with pin that inserts into the top of the pillar, ensuring the pillar cannot be knocked over or blown over during use.
Openings for Cell Access: FIG. 11 illustrates clear openings that allow for easy cell access. All 28 spring covers and retaining clips (Item 43) can be accessed through this opening, simplifying cell maintenance and replacement.
Recess in the Base Plate (Item 44): A specifically designed recess in the base plate accommodates an expanded foam seal. This seal matches the double seal depicted in FIG. 10, ensuring a tight fit that prevents ingress of unwanted substances.
Extruded Polycarbonate Reinforced Insulation (Item 45): The aluminium tubes are covered with extruded polycarbonate reinforced insulation.

This insulation is shaped with recesses, similar to roofing sheets, enhancing the structure's strength and durability.

In conclusion, FIG. 11 elucidates the design considerations incorporated into the base region of the pillar, aiming for stability, ease of cell access, and protection from environmental factors.

### FIG. 12: Design of Plug-and-Play Pillars and Pallets

FIG. 12 provides a comprehensive overview of the key elements in standard pillars and pallets, highlighting the plug-and-play characteristics of these components within the energy storage system.

### Key Elements of FIG. 12

Cross-Brace or Locking Arrangement: The design integrates a mechanism to ensure all pillars are cross-braced or interlocked, so that adjacent pillars operate as a single physical module. This includes either cross-bracing straps, tying the bottom of pillars to the tops of nearby aligned pillars, or an interlocking method that prevents pillars from sliding vertically past each other when strapped together. This feature enhances the pillars' stability during transit and eliminates movement that could compromise the system's reliability. It is crucial in preventing pillar toppling or displacement. The preferred locking device (not shown) is H-shaped, rotated 90 degrees sideways, placed between pillars to provide spacing for airflow, with the legs of the H shape locking above and below the top injection-molded covers.
Under-Pallet Airflow and Vents: The design facilitates efficient heat management within the system by directing cooling air up the sides of the pillars. The space beneath the pallets, which also accommodates forklift prongs, shares this under-pallet air. Risers, which elevate the pallets, are equipped with holes or gaps enabling cross airflow. This dual functionality effectively maintains the optimal performance of the energy storage cells.
Plug and Play Interconnection: Each pillar is equipped with multiple high-power terminals designed for both input and output. This design choice allows for ample pathways for the electrical current, ensuring efficient energy transfer and redundancy. To complement these, fiber optic lines are introduced alongside the electrical connections, serving also as redundant communications pathways to bolster system reliability.
Quick-Release Connections: The design includes quick-release connections for both communication and high current terminals. These connections simplify system installation, configuration, maintenance, and upgrades.
Space for Standard Forks: The pallets are designed with enough clearance underneath for standard forklift prongs, facilitating easy movement. This feature enhances the system's mobility, installation, and flexibility.
Lifting Points on Pillars: To facilitate easy pillar replacement, lifting points are integrated into the pillar design. Once a pallet has been relocated to a service area, these lifting points allow for the easy removal and replacement of pillars.
Standard Size: The preferred pallet is of a standard size, accommodating 4×4 pillars, such that four pallets fit neatly into a 10-foot high cube shipping container.

In summary, FIG. 12 outlines the design elements that contribute to the easy installation, mobility, and maintenance of the pillars and pallets. It underscores the plug-and-play nature of the energy storage system.

### FIG. 13: Wiring Arrangements for Pillar-Based Energy Storage System

FIG. 13 displays potential wiring configurations for an energy storage system utilizing a pillar structure. The flexibility of the system is underscored, originating from the ability of the pillars to self-organize during startup. This self-organization process enables the pillars to autonomously determine the wired topology before users define allowable operational parameters, such as currents and voltages. During this self-organization, the pillars communicate with their adjacent counterparts and electrically exercise their outputs. This action ensures that the electrical interconnections align with the topology determined by the detected communication interconnections. The arrangement is graphically laid out for users to verify that the wiring has been implemented as expected and to visually indicate any failed or indeterminate interconnections.

### Key Elements of FIG. 13

3×3 Pillar Pallet (top left): This arrangement represents a typical star/delta 240V_{ac} system with redundant loops, which ensures operational continuation even if a single pillar fails. The system software adjusts the charge distribution subtly across the pillars within these loops by varying the voltages to control respective current flows, increasing it in overcharged pillars and reducing it in undercharged ones. In this configuration, each delta spans across two pillars, with one pillar reaching the star point.
4×3 Pillar Pallet (middle left): 4×3 Pillar Pallet (middle left): This layout represents a delta 1000V_{ac} system, characterized by a single redundancy loop encompassing the deltas. Similar to the 3×3 pillar pallet, this design preserves system operation even in the event of a pillar failure. The software orchestrates charge distribution by subtly modulating the voltages across the delta loop to adjust the marginal current flows (in addition to any currents entering or exiting the system) between pillars. In this setup, each delta is spanned by four pillars.
4×4 Pillar Pallet (bottom left): This configuration represents another delta 1000V_{ac} system but only includes loops between side-by-side parallel pillars. If a charge transfer between the deltas is necessary, the system employs an externally connected transformer. The software manages charge distribution between the deltas by modulating the voltages to control respective current flows, increasing it in overcharged pillars in one delta string, and reducing it in undercharged pillars in another. An external transformer facilitates current sharing in this arrangement.
4×4 Pillar Pallet with 2×2 Pallets in a 10-Foot Shipping Container (right): This layout, representing a delta 1000V_{ac} system, exhibits multilayer redundancy with loops in both the quad parallel side-by-side pillars and around the three-way delta. Charge transfers between deltas operate as described for the 4×4 pillar pallet. The software assists in the commissioning process by automatically mapping out the topology. As depicted here, two deltas contain five pillars in series, and the third contains six. Each pillar adjusts the current they individually contribute or extract from the power supply to maintain evenly distributed charge levels, adhering to the predefined charging and discharging profiles.

Where loops are present, the system incorporates a feature for stress-testing connections either before commissioning or during maintenance. Initially, the system disconnects from the power supply. The pillars within each loop take turns outputting safe, extra-low voltages, directing high test currents throughout the system, with the non-testing pillars effectively taking a passive role, bypassing the current or alternatively all pillars work to test together, one providing positive and adjacent negative steps or voltages around the loops, thereby reducing the total testing period. This test lasts long enough for any high-resistance joints to heat up, facilitating fault detection using a thermal camera. After completing the tests and checks, the operator can exit the test mode and reconnect the system to the power supply.

In conclusion, FIG. 13 highlights the system's flexibility and adaptability, showcasing a range of configurations to achieve varying levels of redundancy, ease of pre-operation integrity testing and ability to meet diverse voltage requirements.

### Additional Features in the Pillar-Based Energy Storage Systems (Not Shown)

Additional features incorporated within the pillar-based energy storage system, which collectively enhance the system's overall performance, reliability, and ease of maintenance.

### Key Aspects

Paralleled Pillars: Pillars can be paralleled to strengthen reliability, augment storage, or boost current capacity. In this configuration, they work in unison to sum their voltages, either providing or consuming the necessary power.
Charge Management: Pillars in a string or loop communicate and individually fine-tune their voltages to govern their power flow and resulting charge levels, thereby ensuring optimal charge distribution throughout the system.
Testing Mechanisms: Pillars can be disconnected from the power system to undergo various testing procedures, including High Current Test, High Pillar Voltage Stress Test, and High dV/dt Pillar Voltage Stress Test. These tests are integral in monitoring pillar performance and identifying potential aging or defective components.
Leakage Testing: The system performs leakage tests to detect any leakage currents in the system but particularly between cells and the tubes enclosing them, which can signal moisture ingress or insulation degradation. These tests are conducted during the shutdown phase or when there is no need for current flow through a pillar. The pillars drive their voltage either high or low relative to L1 (as shown in FIG. 9) and then isolate their corresponding MOSFETs. Any leakage current is confirmed or alternatively deemed insignificant by measuring voltage droop on the cells and comparing them with the rate of droop anticipated from known currents—like the current required for voltage measurement. This process ensures that any significant leakage is promptly identified and addressed.
Double Insulation: Each pillar is equipped with dual layers of double insulation and insulation overlap to ensure adequate creepage distances, offering enhanced protection to the internal cells.
Cell Replacement: The system design significantly simplifies the process of cell replacement. By tilting the pillars down on their hinges—formed by a stainless steel pin (Item 42), a base plate (Item 40), and the bottom injection molded cover (FIG. 10)—access is granted to the area where releasing by compressing the retaining clips (Item 11) disengage cell spring pushers (Item 12). Following this step, the spring mechanism can be removed, allowing for the access to the end plate PCB. This accessibility facilitates the straightforward removal of old cells and the installation of new ones.
Mounting and Wiring: In the case of mass storage pillars, there might be a slight change to the design presented in FIG. 11. Specifically, the hinge arrangement may not be included if deemed unnecessary. Pillars are designed to fit neatly into recesses on pallets, which simplifies the processes of installation, delivery, and removal. In addition, the pillars are designed with a plug-and-play feature, accommodating dual wiring and communication paths for inbound and outbound connections. It's also important to note that pillars mounted on pallets don't require an additional base plate as the pallet performs this function. Additionally, lifting points incorporated in the bottom injection molded cover (as seen in FIG. 10), allow a purpose-built removal [symbol] trolley to lift and easily remove the pillars.
Overvoltage Surge Protection: The pillars are designed to protect themselves from an overvoltage surge primarily by open-circuiting their MOSFETs. This response acts as a resistance against the surge voltage and redirects any resulting current through the cells and storage capacitors of the compensator, utilizing the body diodes of the open-circuit MOSFETs. In a surge event, the compensator, while monitoring the surge current and voltage on its wave storage capacitors, can either:
Activate dedicated sacrificial series MOSFETs to self-destruct as a final protection measure. These back-to-back sacrificial MOSFETs are fully turned ON during normal operation. However, if a surge occurs and the compensator can no longer absorb the surge, they are triggered to turn OFF and instantaneously self-destruct of the additional voltage does not block the surge. This action provides resistance to a significant further voltage surge, thereby shielding the compensator and the rest of the system from potential damage.
Or Install a Metal Oxide Varistor (MOV) across the compensator and arrange back-to-back MOSFETs between the compensator and the closest optimizer. The MOV possesses a fully turned ON voltage below that of the combined back-to-back MOSFETs combined with the maximum voltage the compensator can handle. In this setup, the MOV carries the surge current, with the compensator and additional layer of MOSFETs resisting the voltage, further protecting the system from damage.

In conclusion, this highlights the sophisticated design features and protections integrated within the pillar-based energy storage system, demonstrating its robustness, operational flexibility, and ease of maintenance.

### Additional features for High Operating Voltages (MV or HV) (not shown)

High voltage operation necessitates additional features that equip the pillar-based energy storage system for higher operating voltages. These features embody the system's adaptability, safety measures, and the proactive stance towards electromagnetic compatibility (EMC).

### Key Aspects for MV or HV

Additional Insulation: In scenarios demanding higher operating voltages, a third layer of insulation is incorporated. This added layer can be strategically placed between pallets and, or used to line a shipping container or room, enhancing the system's safety and reliability.
Safety Measures: Special precautions are implemented to safeguard personnel from potential exposure to high voltage system components while in operation. These measures may include the installation of gates, doors, locks, or warning signs to ensure the secure and safe operation of the system.
EMC Compensation: In high voltage applications, electromagnetic compatibility is managed through the utilization of a shipping container that acts as a Faraday shield or by employing a purpose-built shield. In this arrangement, active compensation can be avoided, the system produces a pure sine wave through stepping, inclusive of PWM into a series-connected choke. Additional filtering facilitated by capacitors generates a smooth and stable waveform, thereby ensuring optimal EMC.

In conclusion, this underscores the flexibility, safety, and adaptability of the pillarbased energy storage system. It provides insights into how the system can be tailored to cater to various applications and voltage requirements, thereby exhibiting its wide operational spectrum.

Each feature includes number items. These items are detailed below:
Item 1—Cells The cells utilized in this example are cylindrical 33140 cells, typically measuring 33 mm in diameter and 140 mm in length. Each cell is encapsulated with a heat-shrunk layer of insulation. This embodiment has been designed for cells with a Lithium Iron Phosphate (LiFePO4) chemical composition. LiFePO4 cells effectively become open-circuit when fully charged or over charged, a state that disrupts the series current charge balancing typically found in lead-acid batteries. This necessitates careful monitoring and balancing to ensure uniform charging across cells of this type. While this model employs LiFePO4 cells, other cell types-potentially with unique materials or alternative chemical compositions-could also be used. These alternative cells might display greater leakage when fully charged, similar to lead-acid cells, thus reducing the need for individual cell balancing and monitoring. In this system, twenty-four cells are connected in series, each with a plateau voltage of 3.2V, leading to a nominal operating voltage of 72V. When the cells are fully charged at 3.6V, this embodiment can reach a maximum voltage of 86.4V.
Item 2—Balancing and Monitoring (BMS) PCB This PCB, slightly longer than an associated cell, features brass or phosphor bronze tabs (Item 18) above and below it (to the left and right in FIG. 5), enabling it to measure and balance voltages at the connections between cells. Each PCB monitors and balances voltages at four points, each end of two associated cells. The BMS PCBs are electrically connected via flexible PCBs enabling the PCBs to be aligned with the tubes for easy insertion without a rigid connection to adjacent connected BMS PCBs. The uppermost PCB has a male edge connection and flange (not shown) to align with an injection molded part (Item 17) facilitating the edge connector being pushed into its mating part when the cells push on the underside of that injection-molded part. The lowermost BMS PCB features a flying lead to the fuse plate (Item 21) for balancing and monitoring the junction of the bottom cells. The BMS is designed to work with mux voltages up to 100V which gives plenty of head room for this system, given its designed maximum working voltage is 86.4V.
Item 3—Insulating Sheet These are flexible rectangular sheets, made from a durable, semi-rigid, flame-retardant insulating material like PVC. They slide 30 into the length of the tubes (Item 6) and overlap the PCB guides (Item 5). The overlap ensures creepage distances are suitable for the applied stepping voltages.
Item 4—Screw Retaining Slots These slots, which are formed into the extruded tube material, are equipped with a flange (not shown) that allows the PCB guides (Item 5) to securely latch onto, thereby holding the guides firmly against the sides of the tubes. The slots are designed to accommodate number 8 selftapping screws.
Item 5—PCB Guide This extruded guide easily slides over the flanges of the screw slots (Item 4), offering a smooth surface for the BMS PCBs to glide into. The guide comes with flanges (shown) that overlap the insulating sheets (Item 3) and retaining segments (not shown) that clip onto the flanges of the screw slots, holding the guides in place against the tube sides.
Item 6—Tubes Made from extruded aluminum, these tubes possess screw slots (Item 4) with flanges designed to secure the PCB guides (Item 5). The tubes are shaped to accommodate the cells, featuring quarter-round corners for quad cell tubes and half-round corners for double cell tubes.
Item 7—Level Switching This feature, depicted diagrammatically, indicates where the switching takes place. Its purpose is to minimize the length of the copper loop through which the current flows. In this example, MOSFETs are arranged back-to-back. This layout allows for direct airflow for cooling the MOSFETs in a virtual corridor. A fan drives air along this path when the system operates at high power levels or when an attached temperature sensor signals that cooling is required.
Item 8—Cell Pack Interconnections and Balancing The oval symbols depicted represent the locations where cell packs interconnect. These interconnections are optimized to make the most of the copper usage while minimizing the path length and may extend across the entire width of the four dual tube cell packs. In FIG. 2B, the interconnection spans from side-to-side, while in FIG. 4B it spans the width of the tube. A typical flying capacitor arrangement is employed, with the capacitor size chosen to prevent a significant imbalance from overloading the associated MOSFETs that switch the flying capacitor levels.

Still, it's large enough to balance the required current at maximum switching frequencies. To ensure the board's reliability, film or ceramic capacitors are used. An inductor is placed in series to create a series-tuned circuit at the desired switching frequency. With the series inductor, the use of a smaller capacitor, and frequency shifting enables overload protection, eliminating the need for further overcurrent protection. Series PTCs (Positive Temperature Coefficient resistors) are considered as potential alternative protection mechanisms.
Item 9—Interconnections In this example, a double row of standard header pins is used for interconnections to associated PCBs, secondary boards that incorporate an inverter, or compensator. Each connection features 40 male/female pins, ensuring a highly reliable, multi-redundant interconnection.
Item 10—Cell Terminal This design employs standard stainless steel round head coach bolts for these top cell terminals. An injection-molded cover, depicted by its edge in (Item 23), includes a recess that the square locating head of the bolt locks into. Also included is a nut that screws down to secure the coach bolt in place. After tightening all 56 bolts, split or thin star washers may be added for improved electrical connection to the PCB (Item 15). The PCB is then placed over the bolts, followed by additional washers (which may be split or star), and the PCB is secured using more nuts. M6 bolts and nuts are utilized in this example.
Item 11—Spring Clips These clips have flanges that hold the spring covers (Item 12) and are screwed down, clamping the bottom injection-molded cover to the aluminum tubes. The screws that retain the clips are driven into the screw slots of the tubes (Item 4). These spring clips allow the spring covers (Item 12) to slide past them. The flanges then spring out, locking against the sides of the recesses of the spring covers, preventing the spring covers from being removed without a suitable tool.
Item 12—Spring Covers Made of thin stainless steel (0.6 mm in this case), the edges of the spring covers are bent up to secure the plastic molded part that locate the springs. The middle of the cover is embossed down the center to 30 prevent the cover from deforming under the spring force that it retains.
Item 13—Reserved
Item 14—BMS Edge Connector The Battery Management System (BMS) is controlled by four lines detailed in FIG. 8. These lines are:
Enable: open circuit or 0V=BMS no channels enabled; Battery positive voltage=All BMS channels enabled.
MuxOn: Toggle 10 to 0V =Switch mux OFF; Toggle 0 to 10V=Switch mux ON.
Mux A: First Mux channel (mux connects to+ve of odd cells)
Mux B: Second Mux channel (mux connects to+ve of even cells).

The edge connector has 6 pins. Mux A and Mux B each connect through two pins of the edge connector for reliability and to sense the battery voltage and carry balancing current as per FIG. 8's description.
Item 15—High-Level BMS This board, designed to manage the ends of all 28 strings of cells as depicted in FIGS. 6 and 7, features immersion gold connections for reliable, corrosion-free connectivity to the coach bolts. Its dual primary functions are:
As per FIG. 6, the board enables high-level balancing of banks of cell strings by adjusting the forward or reverse switching timing.
According to FIG. 7, it allows for high-level balancing of banks of cell strings using a flying capacitor topology.

The design of this board incorporates two medium-power (0.5 A) switching regulators, which can vary their voltages from 0V to the positive battery voltage.

The high-level BMS, also known as the optimizer board (Item 15), interacts with the string BMS (Item 2) to measure and correct a specific cell's voltage or charge level through several steps:
Activation of the Mux System: The Mux system is activated by setting the ‘Enable’ to the battery's positive voltage, assuming it's not already enabled.
MuxOn Alteration: The board toggles ‘MuxOn’ to a low state (0V).
Tube Mux Selection: The board enables the muxes for a chosen one of the four dual tubes by activating the gates of the corresponding MOSFETs mounted on the optimizer board, which electrically connect the regulator to the selected tube (not shown).
Regulator Adjustment: The two switching regulators are set to voltages that approximate two cell voltages. These are typically set to the expected voltage on the positive terminals of adjacent even and odd cells.
Regulator Configuration: The switching regulator is then configured to a high-impedance state with its MOSFETs deactivated, allowing the regulator capacitors to retain the set voltage.
MuxOn Alteration: The board toggles ‘MuxOn’ to a high state (10V).
Cell Connection: The cell with a voltage closest to the set voltage connects as per the guidelines described in FIG. 8.
Mux Voltage Measurement and Charge Adjustment: Each mux voltage is measured. Abnormal or unexpected voltages are recorded and later reported when assessing which cells may need changing prematurely.

The switching regulator is then enabled and adjusted to a voltage suitable for charging or discharging the connected cells. The voltage is measured as the regulator is enabled, and a resulting measured step in voltage is used to estimate the current flow into or out of the selected cell or cells.
Iteration: The entire sequence is repeated for the other cells.

This detailed and methodical process ensures that the high-level BMS boards, in coordination with the optimizer board, provide efficient and effective management of the battery system.
Item 16—Reserved
Item 17—BMS Pusher This molded part attaches to the Battery Management System (BMS) board. It ensures that the BMS is pushed into the tube by the cells, resulting in the BMS being fully driven into its connector when the cells are fully installed against the associated coach bolts.
Item 18—Cell Tabs These tabs protrude above and below the BMS PCB, connecting between cells as illustrated horizontally in FIG. 5. The surfaces of the tabs that mate to the cells are stippled, in this case, to a height of 0.2 mm. The stippling ensures that any corrosion does not result in a separation of mating surfaces. For optimal reliability, silicone grease is applied to the surfaces, and the stippling assists in retaining the grease through capillary action.
Item 19—Terminals These terminals, mounted to the end plate PCB, may be of a similar design to the flanges described in (Item 18). Alternatively, they could be slightly domed to achieve a comparable outcome.
Item 20—Fuse This is a standard surface-mount fuse. For either design, low voltage (<100V_{dc}) fuses are utilized. In the design of FIG. 7, these fuses have a higher current rating than the inverter input fuse, which has a higher voltage rating, so it would blow first.
Item 21—End Plate PCB This connects across the ends of each string of 12 cells and includes a flying lead for the BMS PCB to connect to. This PCB applies significant force, ranging from 4 kg to 20 kg, against each string of cells, ensuring a reliable and long-term electrical connection.
Item 22—Cell String Springs These potent springs are implemented in pairs per dual tube. Fully compressed, they exert a force greater than 10 kg, thereby maintaining all cells within a string in a tightly pressed configuration for optimal performance.
Item 23—Injection Molded Top Cover (Its Bottom Edge) This identifies where the bottom edge of the injection molded cover that is tasked with securely holding all cell tubes in place, ensuring both structural stability and alignment.
Item 24—Bottom BMS PCB to End Plate PCB Wire This wire facilitates the connection between the bottom BMS PCB (Item 2) and the end plate PCB (Item 21). It is designed to be long and robust, allowing for the end plate PCB to be removed when necessary for cell polarity and charge checking. Checking is performed with a dedicated test piece or multimeter. The wire has sufficient strength to serve as a drawstring for pulling cells out of the tubes when required.
Item 25—Control Signal Capacitor/Resistor This component couples the control signal to manage the corresponding multiplexer (mux). The capacitor's rating exceeds the string voltage, enabling it to block the control signal voltage from the mux or cell voltage. It possesses sufficient capacitance to retain the leakage charge on the mux MOSFETs for the duration of the sample period, nominally 1 ms is sufficient. The resistor within this setup limits the current into the desaturation transistors and zener voltage limiter (Item 27), preventing forced turning ON of the mux MOSFETs or the controlling driver from being overloaded when operating multiple BMS PCBs.
Item 26—Emitter Coupled Transistors These transistors are coupled to the joined sources of the mux MOSFETs, with their collectors connected to the gates of the same MOSFETs. Their purpose is to shut off the MOSFETs when they desaturate. The voltage level at which desaturation occurs is set by the resistor dividers, which span across the drains of the MOSFETs to the bases of these desaturation detect transistors.
Item 27—Zener Voltage Limiter This component consists of two transistors wired across the source/gates of the MOSFETs, functioning as a zener to limit the gate voltages. The two transistors are connected in series, with the maximum voltage to the MOSFET gates determined by the series reverse emitter junction breakdowns. Transistors are ideal for this role as they possess a very sharp knee voltage, a result of the reverse breakdown of the emitter-base junction.
Item 28—Enable Input Conditioner This set of components facilitate enabling the multiplexer (mux) or shutting it down to a low power state. The arrangement includes three essential parts: a high-value resistor, a connected diode, [symbol] and a second diode. The high-value resistor serves to bias the connected diode when the mux is enabled. The second diode's role is to pull down the MOSFET gates, shutting off all MOSFETs when the enable input is pulled low.
Item 29—Pulldown Resistor This resistor plays a crucial role in ensuring the MOSFETs remain in an ‘off’ state when not being actively controlled. It achieves this by creating a path for current that ensures the voltage across the MOSFET gates is kept low, preventing them from turning on when the enable input is allowed to float.
Item 30—External Common Mode Choke This component is used to further reduce any conducted emissions in the system. Common mode chokes are a type of electrical filter that help to block interference and noise on a line, in this case the choke is an added layer of noise reduction to ensure minimal interference.
Item 31—Common Connection Point This serves as the junction for a functional earth or shield common point. It's a crucial component that ensures EMI is kept to a minimum while providing grounding of the system, contributing to the overall safety, compliance and functionality of the system.
Item 32—Filtering Component This element filters compensated steps. Notably, it includes a snubber, which consists of a capacitor and resistor, designed to suppress or “snub” ringing from any perturbations that occur from repetitive slightly miss timed steps. The ideal capacitor has been found to range between 0.1× and 0.5× the value of the line capacitors that are placed across the chokes. The optimal resistor has been found to be a 5 W resistor ranging between 10 Ω to 50 Ω when using a 0.47 μF snubbing capacitor.
Item 33—Shield The shield, which comprises three main parts, is used to protect the system and reduce interference. It includes a top shield surrounding PCBs and electrically screwed to the aluminum tube (diagrammatically shown as (Item 35)), the aluminum tubes (Item 34), and the spring covers (Item 12). The spring clips (Item 11) electrically connect these parts.
Item 34—Aluminum Tubes These tubes house the cells, providing shielding and protection against any potential overheating events that could cause damage outside of the pillar.
Item 35—Top Shield This is the part of the top shield that gets screwed to the aluminum tubes. It's a crucial component that provides additional protection and stability to the system.
Item 36—Double Rib This rib is designed to mate with (Item 44), a closed cell or silicone seal located in the base. The double rib can additionally accept a silicone grease bead to create an IP67 waterproof seal or just rest against the [symbol] base seal for an IP65 to IP66 seal.
Item 37—Cell Installation Opening This is the opening through which cells can be installed and removed.
Item 38—Mounting Hole This is the hole in the spring clip and injection molded base for a number 8 self-tapper to secure the clips (Item 11) and base (FIG. 10) to the tubes (Item 6).
Item 39—Spring Clip Compression This item illustrates how the spring clips (Item 11) get compressed to remove or install the spring covers (Item 12).
Item 40—Base Plate The base plate, also injection molded, features horizontal holes on three sides for stainless steel pins to slide into, allowing a hinge action for replacing cells. The pins are installed on both sides to secure the pillar or any of three sides to allow it to lay down in a left, forward or right direction.
Item 41—Screw Holes for Securing Base These are the screw holes for securing the base. The underside has a cross-hatch pattern to seat reliably into wet cement, gap-filling material like liquid nails or epoxy resin. The filling material ensures the base sits securely, stabilised but the gap filling material.
Item 42—Stainless Steel Pins These pins slide the length of one or two sides of the pillar. The bottom injection molded cover has strong flanges with holes to accept these pins, suitable for lifting the weight of the cells and pillar without significant distortion of the base plate (Item 40) or bottom injection molded cover.
Item 43—Spring Cover Assembly The figure identifies two spring covers and more generally to the bottom injection molded cover assembly.
Item 44—Seal Recess The recess for closed cell foam or silicone seal that mates to the double ribs of (Item 36). This seal is designed to create a watertight enclosure when paired with the ribs.
Item 45—Extruded Polycarbonate Reinforced Insulation This insulation is used to cover the aluminium tubes, providing protection and additional strength.

The insulation is shaped with recesses, similar to those in roofing sheets, to enhance its durability. It is produced as four corners and joining pieces at the middle of each side. The bottom injection molded cover has a deep recess that the insulation seats into. The insulation is self-sealing and self-tightening by an interlocking arrangement (not shown) when fitted together and stretched to fit over the tubes. For enhanced IP protection, the bottom is sealed with an open cell foam material placed in the recess before adding the extrusion. In another embodiment, the base is filled with a sealing glued before the insulation is slid into place. The outside flange of the recess is lower than the inside to prevent water from entering the enclosure.

1.-20. (canceled)

21. An energy storage system, comprising:
a plurality of elongated compartments, each designed to house a string of energy storage cells;
each compartment is equipped with accessible openings, engineered to facilitate the easy installation and removal of the storage cells;
the compartments being architected to host two or more storage cells, positioned adjacently within its extremities;
a retaining mechanism is also incorporated, which serves to hold the string of cells firmly pressed together, thereby forming a reliable current path;
the system incorporates a balancing mechanism;
this mechanism includes a balancing system that comprises electrical tabs connecting the junctions of adjacent cells and a mechanism capable of moving charge into and out of these tabs; and
this movement of charge facilitates charging or discharging of the cells, thereby maintaining balanced voltages across the system.

22. The energy storage system of claim 21, wherein the balancing mechanism is equipped with a sensing unit that actively measures the voltage levels of storage cells via a multiplexing apparatus; the system also features a programmable voltage regulator that interfaces with the cells via the multiplexing apparatus; the sensing unit, voltage regulator, and multiplexing apparatus operate in concert to balance the measured or computed voltage levels across the string of energy storage cells housed within each elongated compartment.

23. The energy storage system of claim 21, wherein the balancing mechanism employs a flying capacitor mechanism.

24. The energy storage system of claim 21, wherein the plurality of elongated compartments are formed from aluminium tubes, which incorporate a retaining mechanism for Printed Circuit Boards (PCBs); these PCBs are positioned between two or more cells.

25. The energy storage system of claim 24, wherein a second layer of insulation is applied between the cells and the aluminium; the retaining mechanism is comprised of insulating material that extends beyond the insulation positioned between the cells and aluminium, thereby providing an adequate creepage distance to ensure safe operation given the voltages of the system.

26. The energy storage system of claim 21, wherein an additional layer of insulation is employed to shield external metallic surfaces, thus creating a system with reinforced insulation that safeguards personnel from potentially hazardous voltages.

27. The energy storage system of claim 26, wherein the added layer of insulation consists of extruded interlocking plastic corrugated material.

28. The energy storage system of claim 26, wherein the added layer of insulation comprises one or more layers of wrapping material, where the wrapping material is either a shrinkable material or a vinyl wrap material.

29. The energy storage system of claim 21, wherein the energy storage cells in a string are welded together prior to installation.

30. The energy storage system of claim 21, wherein the tabs of the balancing mechanism incorporate spring pins to make contact with the electrical sensing terminals of the cells.

31. The energy storage system of claim 21, wherein the elongated compartments are vertically mounted onto a base plate; the base plate is detachable via hinge or pin from the elongated compartments, thus aiding in the facilitation of the installation and removal of the cell strings.

32. The energy storage system of claim 21, wherein the cell strings are secured in place by cell string springs, and these cell string springs are further held in position by spring covers.

33. The energy storage system of claim 32, wherein the spring covers are retained by spring clips, and can be released by compressing the tabs of the spring clips using a tool.

34. The energy storage system of claim 32, wherein the spring covers are secured in place by a rotating catch or latch mechanism.

35. The energy storage system of claim 21, wherein an AC voltage suitable for connection to a power system is furnished by a connected inverter.

36. The energy storage system of claim 21, wherein an AC voltage apt for connection to a power system is generated by stepped cell strings that produce a stepwise approximation of a sine wave, and a series-connected compensator that smoothens the voltage steps, thereby creating the AC voltage.

37. The energy storage system of claim 36, wherein the compensator is an active device that creates a waveform corresponding to the difference between the stepwise AC waveform and the desired AC waveform suitable for connection to the power system.

38. The energy storage system of claim 36, wherein the compensator comprises an inductor feeding a filter capacitor.

39. The energy storage system of claim 21, characterised by pillars that generate AC voltage.

40. The energy storage system of claim 39, wherein the pillars are series-connected in a loop and the balance of charges on the storage cells is maintained by minor voltage adjustments, resulting in unbalanced current flow that preferentially charges or discharges one pillar over another.
